(19) United States
(12) Patent Application Publication
(10) Pub. No.: US 2024/0258103 A1
(43) Pub. Date: Aug. 1, 2024

(54) PLASMA TREATMENT OF BARRIER AND LINER LAYERS

(71) Applicant: Applied Materials, Inc., Santa Clara, CA (US)

(72) Inventors: Jiajie Cen, San Jose, CA (US); Ge Qu, Sunnyvale, CA (US); Shinjae Hwang, Santa Clara, CA (US); Zheng Ju, Sunnyvale, CA (US); Yang Zhou, Milpitas, CA (US); Zhiyuan Wu, San Jose, CA (US); Feng Chen, San Jose, CA (US); Kevin Kashefi, San Ramon, CA (US)

(73) Assignee: Applied Materials, Inc., Santa Clara, CA (US)

(21) Appl. No.: 18/422,656

(22) Filed: Jan. 25, 2024

Related U.S. Application Data
(60) Provisional application No. 63/482,051, filed on Jan. 29, 2023.

(51) Int. Cl. H01L 21/02; H01L 21/768

(52) U.S. Cl. CPC H01L 21/02274; H01L 21/76814; H01L 21/76826; H01L 21/76843

(57) ABSTRACT

Embodiments of the disclosure relate to methods for forming electrical interconnects. Additional embodiments provide methods of forming and treating barrier and liner layers to improve film and material properties. In some embodiments, the resulting composite layers provide improved resistivity, decrease void formation and improve device reliability.

### CROSS-REFERENCE TO RELATED APPLICATIONS

This application claims priority to U.S. Provisional Application No. 63/482,051, filed Jan. 29, 2023, the entire disclosure of which is hereby incorporated by reference herein.

### TECHNICAL FIELD

Embodiments of the disclosure generally relate to methods of treating liner layers and barrier layers for improved performance. In particular, embodiments of the disclosure pertain to methods for plasma treatment of liner layers and barrier layers which improve layer properties as well as gapfill properties and behavior.

### BACKGROUND

Microelectronic devices, such as semiconductors or integrated circuits, can include millions of electronic circuit devices such as transistors, capacitors, etc. To further increase the density of devices found on integrated circuits, even smaller feature sizes are desired. To achieve these smaller feature sizes, the size of conductive lines, vias, and interconnects, gates, etc. must be reduced. Reliable formation of multilevel interconnect structures is also necessary to increase circuit density and quality.

Advances in fabrication techniques have enabled use of copper for conductive lines, interconnects, vias, and other structures. However, electromigration in interconnect structures becomes a greater hurdle to overcome, with decreased feature size and the increased use of copper for interconnections. Such electromigration may adversely affect the electrical properties of various components of the integrated circuit. Additionally, the use of copper for conductive fill often requires the use of a metal liner to promote nucleation and proper gapfill performance.

Specifically, for the 5 nm node and below, barrier and liner thickness for copper interconnects becomes even more challenging with respect to device reliability and adhesion of the barrier layer to a dielectric layer. Shrinking geometries also result in higher resistance as well as greater susceptibility to electro-migration (EM) failures in the copper lines. A high-quality bond at the interface between the copper and dielectric barrier layer can reduce or prevent EM failures. Traditional techniques for improving nucleation and bonding of the gapfill metal to the underlying barrier layer usually rely on metal or metal alloy liners.

A typical thickness of a barrier layer and liner at the 5 nm node is on the order of about 40 Å to about 45 Å. Thicker barrier/liner layers result in less space for metal gap fill and tend to increase resistivity. The current approach to improve barrier to metal adhesion and filling metal mobility during gap fill is to increase film thickness of the barrier/liner. However, this approach is limited by material properties and thicknesses.

Therefore, there is a need for treatment processes which improve one or more of barrier efficacy, barrier thickness, liner thickness, gapfill adhesion, gapfill nucleation, or gapfill resistivity.

### SUMMARY

One or more embodiments of the disclosure are directed to a method of forming electrical interconnects which comprises forming a barrier layer within a substrate feature, forming a liner layer on the barrier layer, and treating the liner layer and the barrier layer to form a treated composite. The barrier layer is not densified before deposition of the liner layer.

Additional embodiments of the disclosure are directed to a method of forming electrical interconnects. The method comprises forming a barrier layer within a substrate feature, treating the barrier layer to form a treated barrier layer, forming a liner layer on the treated barrier layer, and treating the liner layer and the treated barrier layer to form a treated composite.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates a process flow of a method in accordance with one or more embodiments of the disclosure;

FIGS. 2A through 2E illustrate a substrate during processing in accordance with one or more embodiments of the disclosure; and

FIGS. 3A through 3E illustrate a substrate during various stages of processing in accordance with one or more embodiments of the disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

The term “about” as used herein means approximately or nearly and in the context of a numerical value or range set forth means a variation of ±15% or less, of the numerical value. For example, a value differing by ±14%, ±10%, ±5%, ±2%, ±1%, ±0.5%, or ±0.1% would satisfy the definition of “about.”

As used in this specification and the appended claims, the term “substrate” or “wafer” refers to a surface, or portion of a surface, upon which a process acts. It will also be understood by those skilled in the art that reference to a substrate can refer to only a portion of the substrate, unless the context clearly indicates otherwise. Additionally, reference to depositing on a substrate can mean both a bare substrate and a substrate with one or more films or features deposited or formed thereon.

A “substrate surface” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal and/or bake the substrate surface. In addition to film processing directly on the surface of the substrate itself, in the present disclosure, any of the film processing steps disclosed may also be performed on an under-layer formed on the substrate as disclosed in more detail below, and the term “substrate surface” is intended to include such under-layer as the context indicates. Thus, for example, where a film/layer or partial film/layer has been deposited onto a substrate surface, the exposed surface of the newly deposited film/layer becomes the substrate surface.

The substrate surface may have one or more features formed therein, one or more layers formed thereon, and combinations thereof. The shape of the feature can be any suitable shape including, but not limited to, trenches, holes and vias (circular or polygonal). As used in this regard, the term “feature” refers to any intentional surface irregularity. Suitable examples of features include but are not limited to trenches, which have a top, two sidewalls and a bottom extending into the substrate, and vias which have one or more sidewall extending into the substrate to a bottom.

The term “on” indicates that there is direct contact between elements. The term “directly on” indicates that there is direct contact between elements with no intervening elements.

As used in this specification and the appended claims, the terms “precursor”, “reactant”, “reactive gas” and the like are used interchangeably to refer to any gaseous species that can react with the substrate surface.

Embodiments of the disclosure advantageously provide methods for forming electrical interconnects. Specific embodiments advantageously provide methods of depositing a metal gapfill within a substrate feature lined with a barrier layer and a liner layer that have been treated with one or more plasma treatment processes. In some embodiments, the method decreases the thickness of the barrier layer, decreases the thickness of the liner layer, increases the grain size of the liner layer, lowers the resistivity of the liner layer, lowers the resistivity of the metal gapfill, decreases void volume in the metal gapfill or facilitates integration of one or more of the method operations.

The embodiments of the disclosure are described by way of the Figures, which illustrate processes, substrates and apparatus in accordance with one or more embodiments of the disclosure. The processes, schema and resulting substrates shown are merely illustrative of the disclosed processes, and the skilled artisan will recognize that the disclosed processes are not limited to the illustrated applications.

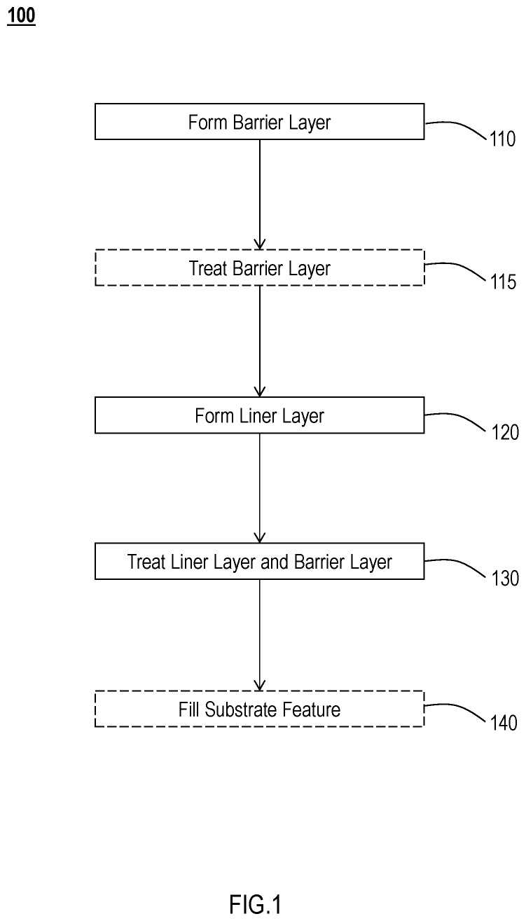

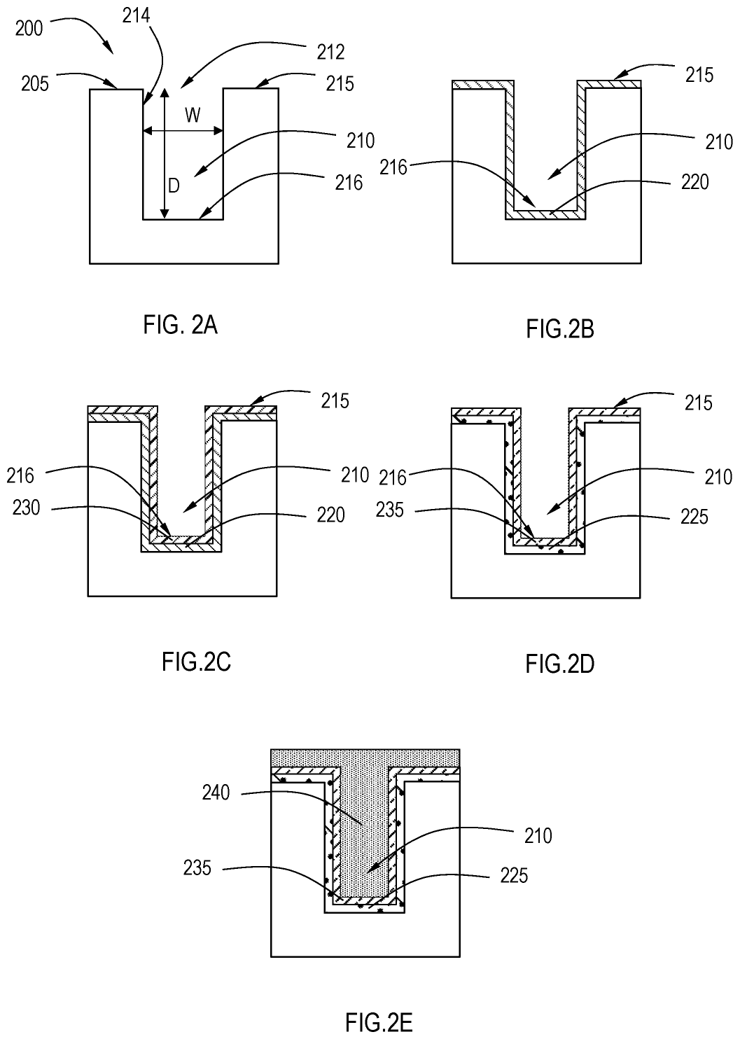

Referring to the Figures, the disclosure relates to a method 100 of treating a barrier layer and a liner layer. FIG. 1 depicts a process flow diagram of a method 100 in accordance with one or more embodiment of the present disclosure. FIGS. 2A-2E depict a substrate 200 during processing according to one or more embodiment of the present disclosure.

FIG. 2A illustrates a substrate 200 with a substrate surface 205. As identified above, the substrate surface refers to the exposed surface of the substrate upon which a layer may be formed. In some embodiments, the substrate 200 comprises a dielectric material. In some embodiments, the substrate 200 comprises a low-k dielectric material.

The substrate surface 205 has at least one feature 210 formed therein. While only a single feature is shown in the Figures, one skilled in the art will recognize that a plurality of features will be affected by the disclosed methods, each in a similar manner.

The at least one feature 210 has an opening 212 with a width W. The opening 212 is formed in a top surface 215 of the substrate 200. The feature 210 also has one or more sidewall 214 and extends a depth D from the top surface 215 to a bottom 216. While straight, vertical sidewalls are shown in the Figures, the disclosed methods may also be performed on slanted, irregular or reentrant sidewalls.

In some embodiments, the width W of the opening 212 is greater than or equal to about 10 nm, greater than or equal to about 15 nm, greater than or equal to about 20 nm, greater than or equal to about 25 nm, greater than or equal to about 30 nm, or greater than or equal to about 35 nm. In some embodiments, the width W is in a range of about 5 nm to about 15 nm, or in a range of about 10 nm to about 35 nm.

In some embodiments, the depth D of the feature 210 is greater than or equal to about 50 nm, greater than or equal to about 75 nm, greater than or equal to about 100 nm, greater than or equal to about 150 nm, greater than or equal to about 200 nm, or greater than or equal to about 250 nm. In some embodiments, the depth D is in a range of about 50 nm to about 250 nm, or in a range of about 200 nm to about 250 nm.

Those skilled in the art will recognize the increasing challenge of depositing metal gapfill in features of narrowing width (also known as critical dimension (CD)) and/or increasing depth. The aspect ratio of the at least one feature 210 is defined as the depth D of the feature 210 divided by the width W. In some embodiments, the at least one feature has an aspect ratio (D:W) greater than or equal to about 2:1, greater than or equal to about 5:1, greater than or equal to about 10:1, or greater than or equal to about 20:1.

Referring to FIGS. 1 and 2B, the method 100 begins with operation 110. At 110, a barrier layer 220 is formed on the substrate surface 205 and within the at least one feature 210. In some embodiments, the barrier layer 220 is formed directly on the substrate surface 205. In some embodiments, as shown in FIG. 2B, the barrier layer 220 is continuous and deposited on the top surface 215, the sidewalls 214 and the bottom 216.

In some embodiments, the barrier layer is substantially conformal over the surface of the substrate feature 210. As used in this regard, a layer which is “substantially conformal” has an average thickness which varies by less than 10%, less than 5% or less than 2% of the average thickness of the layer. In some embodiments, the barrier layer has an average thickness of less than 20 Å, or less than 15 Å.

In some embodiments, operation 110 represents atomic layer deposition (ALD) process. In some embodiments, the ALD deposition process comprises sequentially exposing the substrate surface to a metal precursor and a reactant to form the barrier layer 220. In some embodiments, the barrier layer comprises or consists essentially of tantalum nitride. As used in this regard, a layer which “consists essentially of” a stated material comprises greater than about 95%, greater than about 98%, greater than about 99%, or greater than about 99.5% of the stated material.

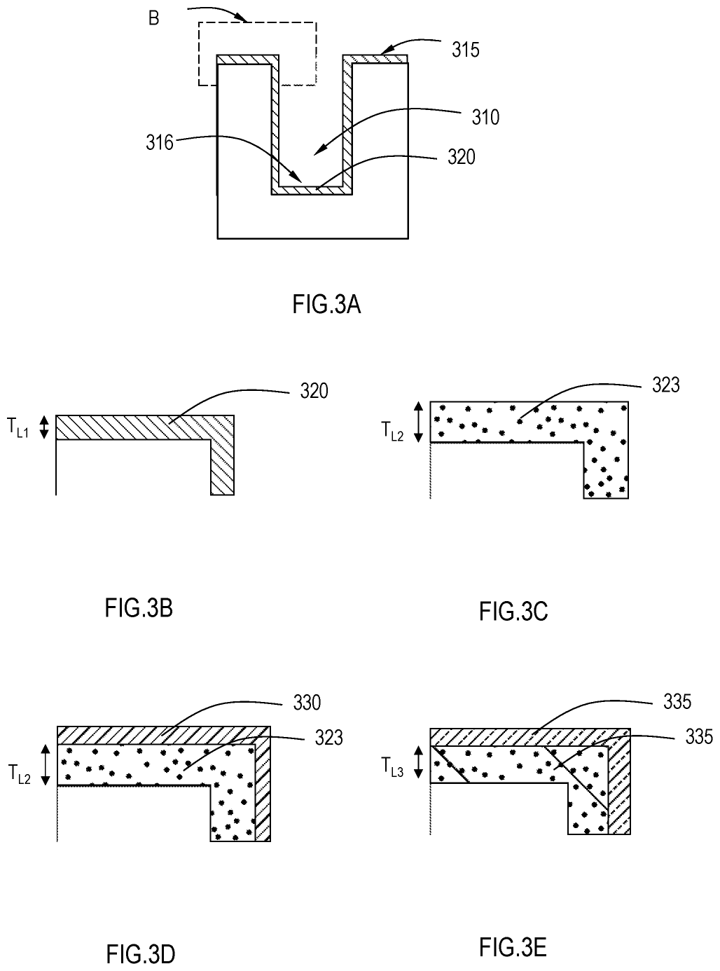

In some embodiments, the method 100 continues to optional operation 115 with a treatment of the barrier layer. Operation 115 is described more fully below with respect to FIGS. 3A-3E. In some embodiments, operation 115, also referred to as a densification treatment is not performed.

The method 100 continues to operation 120. At 120, a liner layer 230 is formed on the barrier layer 220 (or the treated barrier layer 323). In some embodiments, the liner layer 230 is formed directly on the barrier layer 220 (or the treated barrier layer 323).

In some embodiments, operation 120 represents chemical vapor deposition (CVD) process. In some embodiments, operation 120 represents an atomic layer deposition (ALD) process. In some embodiments, the liner layer 230 is substantially conformal over the surface of the barrier layer 220 (or the treated barrier layer 323). In some embodiments, the liner layer 230 comprises or consists essentially of cobalt and/or ruthenium. In some embodiments, the liner layer 230 consists essentially of ruthenium and cobalt, a cobalt/ruthenium alloy or ruthenium doped cobalt.

The method 100 continues to operation 130. At 130, the liner layer 230 and the barrier layer 220 (or the treated barrier layer 323) are treated to form a treated liner layer 235 and a treated barrier layer 225. For simplicity, the treated liner layer 235 and the treated barrier layer 225 may be collectively referred to as the treated composite.

In some embodiments, treating the liner layer 230 and the barrier layer 220 comprises exposing the liner layer to a second plasma formed from a second plasma gas comprising hydrogen gas. In some embodiments, the second plasma gas comprises one or more noble gases (e.g., helium, neon, argon, krypton, xenon). In some embodiments, the second plasma gas comprises both hydrogen gas and one or more noble gases. In some embodiments, the noble gas consists essentially of argon. Accordingly, in some embodiments, the second plasma is referred to as a H₂/Ar plasma.

In some embodiments, the second plasma is an inductively coupled plasma (ICP). In some embodiments, the second plasma is a capacitively coupled plasma (CCP). In some embodiments, the second plasma is remote. In some embodiments, the second plasma is direct. In some embodiments, the second plasma is a mixture of remote and direct.

In some embodiments, the second plasma is an RF plasma. In some embodiments, the RF frequency is selected from about 2 MHz, about 13.56 MHz, about 27 MHz, about 40 MHz, or about 60 MHz. In some embodiments, the RF frequency is in a range of about 2 Mz to about 60 MHz.

In some embodiments, the second plasma has a power in a range of about 100 W to about 1000 W, in a range of about 100 W to about 500 W, or in a range of about 500 W to about 1000 W. In some embodiments, the second plasma has a bias power in a range of 0 W to about 500 W.

In some embodiments, the substrate 200 (including the barrier layer 220 and the liner layer 230) is maintained at a predetermined temperature during exposure to the second plasma. In some embodiments, the predetermined temperature is in a range of about 20° C. to about 400° C., in a range of about 20° C. to about 200° C., or in a range of about 200° C. to about 400° C.

In some embodiments, the liner layer 230 is exposed to the second plasma at a pressure in a range of 0.1 mTorr to 1 Torr. In some embodiments, the pressure is in a range of 0.1 mTorr to 0.1 Torr, in a range of 0.1 mTorr to 10 mTorr, or in a range of 0.1 mTorr to 1 mTorr.

For the avoidance of doubt, operation 115, discussed below comprises a first plasma formed from a first plasma gas. The ordinals used herein are intended to refer to the order in which the treatments may be applied even though they are discussed herein in the opposite order.

Without being bound by theory, it is believed that the plasma treatment performed at operation 130 modifies the composition and properties of both the liner layer and the barrier layer. In some embodiments, the liner layer is densified by the plasma treatment. In some embodiments, the barrier layer is densified by the plasma treatment. In some embodiments, the method lowers the resistivity of the treated composite as compared to the barrier layer and the liner layer without the disclosed treatment by the second plasma.

In some embodiments, the method removes impurities (e.g., carbon, nitrogen, oxygen) from the barrier layer and/or the liner layer. In some embodiments, the method increases the grain size of the barrier layer and/or the liner layer. Again, without being bound by theory, it is believed that this increase in grain size and/or impurities impacts the reflow of a later deposited metal fill within the feature.

In some embodiments, the method 100 continues to operation 140. At operation 140, a metal fill 240 is deposited on the treated composite. In some embodiments, the metal fill 240 is only deposited within the substrate feature. In some embodiments, the metal fill 240 is deposited directly on the treated liner layer 235.

In some embodiments, the metal fill is deposited by a physical vapor deposition (PVD) process. In some embodiments, the metal fill comprises or consists essentially of copper. In some embodiments, the metal fill is free of substantial voids. As used in this regard, a “substantial” void is greater than or equal to 1 nm in width.

The inventors have found that the disclosed plasma treatment methods also advantageously enable greater processing throughput by minimizing the transfer of substrates between processing chambers. For example, in some embodiments, the plasma treatment at operation 130 and the metal deposition at operation 140 can be performed in the same chamber.

Additional embodiments of the disclosure are described below with reference to FIGS. 1 and 3A to 3E. FIG. 3A illustrates a substrate 300 similar to the substrate 200 shown in FIG. 2B. The 300 series reference numerals refer to similar materials as those described above with 200 series reference numerals. FIG. 3A identifies a region B which is enlarged in the subsequent Figures.

After operation 110, FIG. 3B illustrates a substrate 300 with a barrier layer 320 formed thereon. The barrier layer 320 has a thickness T_{B1}. In some embodiments, as indicated above, the method 100 comprises operation 115. At operation 115, the barrier layer 320 is treated before deposition of the liner layer to form a treated barrier layer 323. The treated barrier layer 323 has a thickness T_{B2} greater than the thickness T_{B1} of the barrier layer 320.

In some embodiments, treating the barrier layer 320 comprises exposing the barrier layer to a first plasma formed from a first plasma gas. In some embodiments, the first plasma gas comprises one or more noble gases (e.g., helium, neon, argon, krypton, xenon). In some embodiments, the noble gas consists essentially of argon. In some embodiments, the first plasma gas further comprises hydrogen gas. Accordingly, in some embodiments, the first plasma is referred to as a H₂/Ar plasma.

In some embodiments, the first plasma is an inductively coupled plasma (ICP). In some embodiments, the first plasma is a capacitively coupled plasma (CCP). In some embodiments, the first plasma is remote. In some embodiments, the first plasma is direct. In some embodiments, the first plasma is a mixture of remote and direct.

In some embodiments, the first plasma is an RF plasma. In some embodiments, the RF frequency is selected from about 2 MHz, about 13.56 MHz, about 27 MHz, about 40 MHz, or about 60 MHz. In some embodiments, the RF frequency is in a range of about 2 Mz to about 60 MHz.

In some embodiments, the first plasma has a power in a range of about 100 W to about 1000 W, in a range of about 100 W to about 500 W, or in a range of about 500 W to about 1000 W. In some embodiments, the first plasma has a bias power in a range of 0 W to about 500 W.

In some embodiments, the substrate 300 is maintained at a predetermined temperature during exposure to the first plasma. In some embodiments, the predetermined temperature is in a range of about 20° C. to about 400° C., in a range of about 20° C. to about 200° C., or in a range of about 200° C. to about 400° C.

In some embodiments, the substrate 300 is exposed to the first plasma at a pressure in a range of 0.1 mTorr to 1 Torr. In some embodiments, the pressure is in a range of 0.1 mTorr to 0.1 Torr, in a range of 0.1 mTorr to 10 mTorr, or in a range of 0.1 mTorr to 1 mTorr.

The method 100 continues, as described above, to operation 120. At operation 120, the liner layer 330 is deposited. In some embodiments, operation 120 does not change the thickness T_{B2} of the treated barrier layer 323.

The method continues, as described above, to operation 130. At operation 130, the liner layer 330 and the treated barrier layer 323 are treated to form a treated liner layer 335 and a treated barrier layer 325, also referred to as the treated composite.

The inventors have surprisingly found that in addition to the benefits identified above, when the barrier layer is treated, as disclosed with respect to operation 115, the resulting treated barrier layer 325 has a thickness T_{B3} which is less than the thickness T_{B2} of treated barrier layer 323. In some embodiments, the thickness T_{B2} of the treated barrier layer 323 is reduced by as much as 1 Å. In some embodiments, the thickness is reduced by 0.1 Å to 1 Å, by 0.2 Å to 1 Å, or by 0.5 Å to 1 Å.

The inventors have also surprisingly found that in addition to the benefits identified above, when the barrier layer and the liner layer are treated, as disclosed with respect to operation 130, the resulting treated composite has a thickness which is less than the thickness of the barrier layer 220 and the liner layer 230. In some embodiments, the thickness of the treated composite is up to 3 Å less than the combined thickness of the barrier layer 220 and the liner layer 230 before operation 130. In some embodiments, the thickness is reduced by 0.5 Å to 3 Å, by 1 Å to 3 Å, or by 2 Å to 3 Å.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

What is claimed is:

1. A method of forming electrical interconnects, the method comprising:
forming a barrier layer within a substrate feature;
forming a liner layer on the barrier layer; and
treating the liner layer and the barrier layer to form a treated composite, wherein the barrier layer is not densified before deposition of the liner layer.

2. The method of claim 1, wherein treating the liner layer and the barrier layer comprises exposing the liner layer to a second plasma formed from a second plasma gas comprising hydrogen gas.

3. The method of claim 2, wherein the second plasma gas further comprises a noble gas.

4. The method of claim 3, wherein the noble gas consists essentially of argon.

5. The method of claim 2, wherein the second plasma is an inductively coupled RF plasma.

6. The method of claim 2, wherein the liner layer is exposed to the second plasma at a pressure in a range of 0.1 mTorr to 1 Torr.

7. The method of claim 1, wherein the method lowers the resistivity of the treated composite as compared to the barrier layer and the liner layer without treatments.

8. The method of claim 1, wherein treating the liner layer and the barrier layer increases a grain size of the liner layer.

9. The method of claim 1, wherein treating the liner layer and the barrier layer provides the treated composite with a thickness up to 3 Å less than a cumulative thickness of the liner layer and the barrier layer before treatment.

10. The method of claim 1, further comprising depositing a metal fill on the treated composite within the substrate feature.

11. The method of claim 10, wherein the metal fill is free of substantial voids.

12. The method of claim 10, wherein the metal fill is deposited by PVD in the same chamber as treating the liner layer and the barrier layer.

13. A method of forming electrical interconnects, the method comprising:
forming a barrier layer within a substrate feature;
treating the barrier layer to form a treated barrier layer;
forming a liner layer on the treated barrier layer; and
treating the liner layer and the treated barrier layer to form a treated composite.

14. The method of claim 13, wherein treating the barrier layer comprises exposing the barrier layer to a first plasma formed from a first plasma gas consisting essentially of argon.

15. The method of claim 13, wherein treating the liner layer and the treated barrier layer decreases the thickness of the treated barrier layer and/or the liner layer in the treated composite.

16. The method of claim 15, wherein the thickness of the treated barrier layer and/or the liner layer is reduced by up to 3 Å.

17. The method of claim 13, wherein treating the liner layer and the treated barrier layer comprises exposing the liner layer to a second plasma formed from a second plasma gas comprising hydrogen gas.

18. The method of claim 17, wherein the second plasma gas further comprises a noble gas.

19. The method of claim 18, wherein the noble gas consists essentially of argon.

20. The method of claim 17, wherein the second plasma is an inductively coupled RF plasma.

21. The method of claim 17, wherein the liner layer is exposed to the second plasma at a pressure in a range of 0.1 mTorr to 1 Torr.
